(19) United States
(12) Patent Application Publication
(10) Pub. No.: US 2010/0181501 A1
(43) Pub. Date: Jul. 22, 2010

(54) APPARATUS FOR SUB-ZERO DEGREE C ION IMPLANTATION

(76) Inventor: John D. Pollock, Rowley, MA (US)

Correspondence Address: STOUT, UXA, BUYAN & MULLINS LLP, 4 VENTURE, SUITE 300, IRVINE, CA, 92618, US

(21) Appl. No.: 12/357,320

(22) Filed: Jan. 21, 2009

(51) Int. Cl. H01J 37/20

(52) U.S. Cl. 250/492.21

(57) ABSTRACT

An ion implanter that comprises a chuck assembly having a chuck to clamp, hold, and cool a wafer is disclosed. The chuck is cooled by a cooling assembly circulated with a special coolant, such that the chuck can be maintained at very low temperatures. A mechanical design is provided to minimize the direct surface-to-surface contact area between the chuck and a base, which is employed to support the chuck. The mechanical design includes fasteners for providing mechanical support between the chuck and the base and thermal insulators for providing thermal insulation between the chuck and the base.

### FIELD OF THE INVENTION

The present invention relates to an ion implanter operating in environments under sub-zero temperature, and more particularly, to an ion implanter that effectively thermally insulates the wafer and the chuck from other portions of the ion implanter.

### DESCRIPTION OF THE PRIOR ART

Generally, an ion implanter includes an ion source placed inside an ion source chamber. The ion source chamber connects to an extraction voltage source for extracting ions for projecting an ion beam to a beam analyzer provided with an analyzer magnet. The beam analyzer adjusts the ion beam and may project the ion beam through a plasma shower for carrying out a beam neutralization process. The ion beam then reaches a target wafer that is moved in and out such that the target wafer can be scanned by the ion beam.

During ion implantation for the making of semiconductor devices, keeping the wafer at a low temperature is advantageous for the reduction of implant damage, avoidance of a self-annealing effect, and so on. Semiconductor devices implanted at low temperatures have features of low current leakage, low parasitic capacitance, and low parasitic resistance, and consequently have high reliability and low distortion output signals even after long-term operation at high temperature.

Generally, a chuck is employed to clamp and hold a wafer during ion implantation. To keep wafers at low temperatures during ion implantation, the chuck typically is connected to a water chiller. Therein, a gas also may be applied to the backside of the wafer to bring heat away. FIG. 1 shows a block diagram illustrating a chuck 10 typically cooled by a water chiller 2 according to the prior art. The water chiller 2 circulates DI water (distilled water or deionized water) as the coolant. The DI water is pumped by a pump 4 from a DI reservoir 6 to a DI supply manifold 8 and then fed to the chuck 10 through a control valve 12. A flow sensor 14 gauges the flow rate through the chuck. A thermal meter 16 measures the temperature of the DI reservoir 6, and a pressure gauge 18 senses the pressure of the DI supply manifold 8. Moreover, heat exchanger 19 is used to bring heat away from the DI. Heat exchanger 19 receives a cooling water, or other coolant, through a facility inlet and outputs the cooling water, or other coolant, through a facility outlet after there is a heat exchange between the DI and the cooling water (coolant).

With the critical dimension of semiconductor devices continuously decreasing, especially as ultra shallow junctions become more important, low temperature ion implantations in which wafer temperature is held below 0° C. during ion implantation becomes more necessary. Such requirements call for a detailed heat transfer analysis of the wafer to chuck assembly, because any heat source may transfer heat to the wafer thus causing the wafer temperature to be raised.

FIG. 2 shows a standard electrostatic chuck assembly 26 according to the prior art. A chuck 20 of electrostatic type is used to clamp, hold, and cool a wafer (not shown) during ion implantation. The electrostatic chuck 20 is bolted to the top of a base 22 (which can be viewed as a portion of an ion implanter) with multiple screws 24. The base 22 provides a mechanism to support the chuck 22 and provides space to arrange cooling tubes or electrical connections.

During implantation, ion beams are absorbed in the top surface of the wafer causing its temperature to rise. To maintain the wafer temperature at an acceptable range, heat caused by the ion beams must ultimately be transferred from the surface of the wafer to the coolant circulating within the chuck (the heat also can be transferred to the gas for carrying heat away). The heat transfer follows the following path sequence: 1) through the wafer; 2) across the wafer/chuck 20 interface; and 3) through a portion of the chuck 20 to the water jacket inside the chuck 20.

The largest thermal resistance in the heat transfer path is typically the wafer/chuck interface, this being a reason to use the gas to bring heat away from here. Moreover, the majority of heat is transferred out via the cooling water, but a small amount of heat is also lost to the base 22 and even to other portions of the ion implanter connected to the base 22. Essentially, the slight rise in base temperature that may occur is non-problematical. Therefore, in the prior art, no special precautions are taken to isolate the chuck from the base.

However, for the requirement of maintaining the wafer temperature below 0° C., the above prior art is not without problems. First, the cooling technique described above suffers in that the DI water may freeze at atmospheric pressure. In other words, the conventional technique could not properly operate under 0° C. Second, there is no precaution to thermally isolate the chuck from the base. Hence, heat may be transferred from the base to the wafer through the chuck, causing the wafer temperature to be raised.

Therefore, it would be advantageous to provide an apparatus for sub-zero degree C. ion implantation to improve the deficiencies of the prior art.

### SUMMARY OF THE INVENTION

The present invention provides an apparatus for sub-zero degree C. temperature maintenance of a chuck assembly or an ion implanter during ion implantation, to overcome the deficiencies of the prior art.

The invention provides a chuck assembly comprising a chuck capable of holding a wafer, a base capable of connecting to a portion of an implanter, and at least one fastener that mounts the chuck on the base, such that the chuck and the base have no direct surface-to-surface contact.

The invention also provides an ion implanter comprising an ion beam generation assembly for generating an ion beam and a chuck assembly, where the chuck assembly comprises a chuck capable of holding a wafer to be implanted by the ion beam, a base capable of connecting to a portion of the ion implanter, and at least one fastener that mounts the chuck on the base, such that the chuck and the base have no direct surface-to-surface contact.

### BRIEF DESCRIPTION OF THE DRAWINGS

FIG. 1 shows a block diagram illustrating a chuck typically cooled by a water chiller according to the prior art.

FIG. 2 shows a standard electrostatic chuck assembly according to the prior art.

FIG. 3 shows a cross-sectional view illustrating a chuck assembly according to one embodiment of the present invention.

FIG. 4 shows variant fasteners of embodiments according to the present invention.

FIG. 5 shows a chuck assembly that comprises a fastener thermally insulated from the base by a first thermal insulator according to an embodiment of the present invention.

FIG. 6 shows a chuck assembly that comprises a fastener thermally insulated from the chuck by a second thermal insulator according to an embodiment of the present invention.

FIG. 7 shows a chuck assembly that comprises a chuck thermally insulated from the base by a third thermal insulator according to an embodiment of the present invention.

FIG. 8 shows a chuck assembly that comprises a chuck thermally insulated from the base by a fourth thermal insulator according to an embodiment of the present invention.

FIG. 9 shows a block diagram of an ion implanter that comprises a chuck cooled by a cooling assembly according to an embodiment of the present invention.

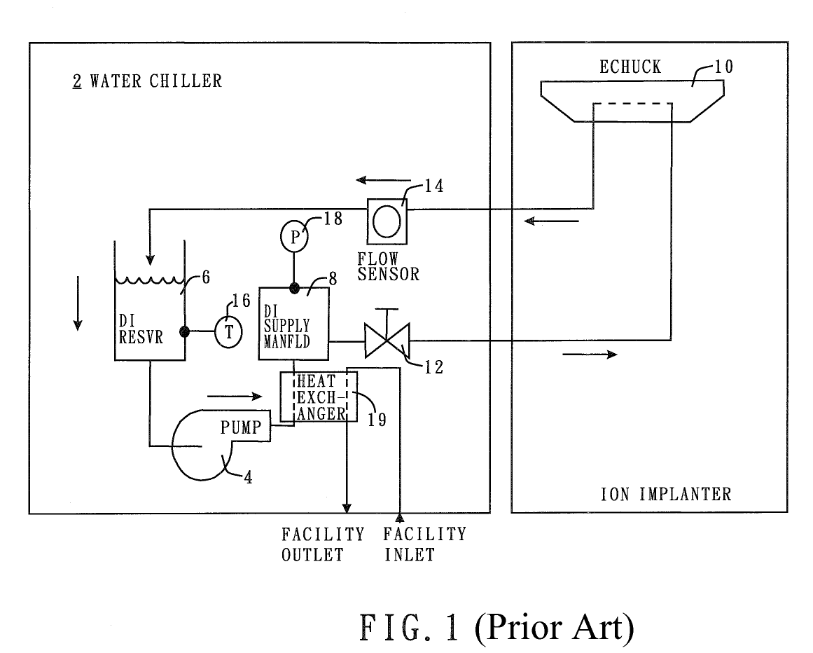

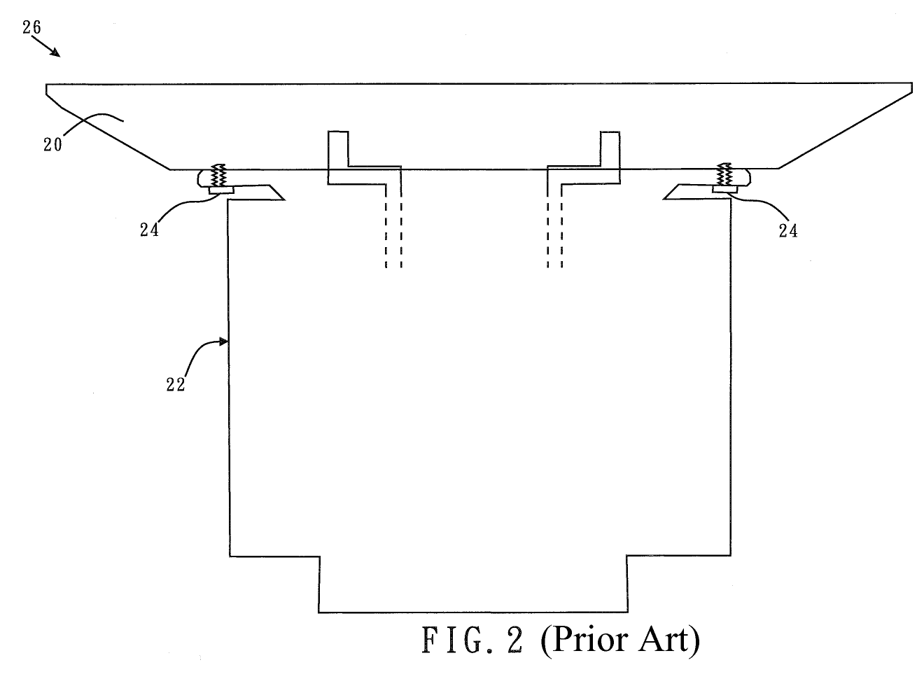

### DESCRIPTION OF THE PREFERRED EMBODIMENT

The detailed description of the present invention will be discussed in the following embodiments, which are not intended to limit the scope of the present invention and which can be adapted for other applications. While the drawings are illustrated in detail, it is appreciated that the quantity of the disclosed components may be greater or less than that disclosed except where expressly restricted. Wherever possible, the same or similar reference numbers are used in the drawings and description to refer to the same or like parts. It should be noted that any drawing presented is in simplified form and is not to precise scale. In reference to the disclosure herein, for purposes of convenience and clarity only, directional terms are used with respect to the accompanying drawings and should not be construed to limit the scope of the invention in any manner.

The present invention discloses an ion implanter that comprises an ion beam generation assembly to generate an ion beam and a chuck assembly to clamp, hold, and cool a wafer during implantation. Certain details of the ion beam generation assembly are not included. It is to be understood that any available or commercial product can be used in any combination according to the knowledge of one skilled in the art, and detailed drawings and descriptions of such items are thus omitted. The ion beam generation assembly comprises an ion source, an extraction voltage, and an analyzer magnet.

One approach of the invention is to change the mounting between the chuck and the base to improve the above deficiencies of the prior art. Herein, both the chuck and the base are not obviously changed, and then both the conventional chuck and the conventional base still can be used. The change is focused on how to minimize the direct surface-to-surface contact between the chuck and the base. In other words, it is focused on the interface between the chuck and the base.

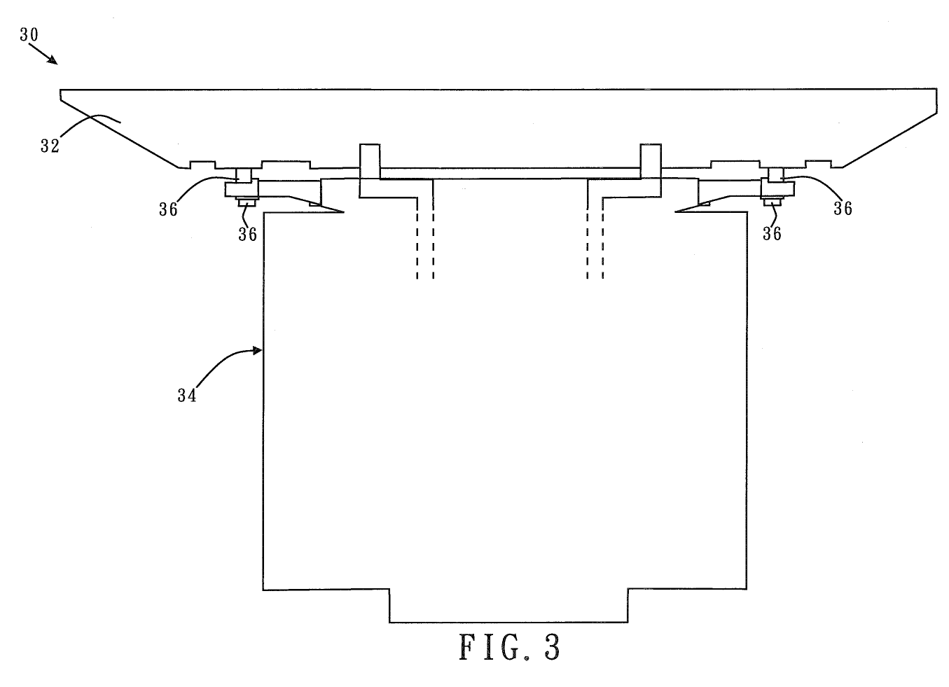

According to one embodiment, as exemplified by the chuck assembly 30 shown in FIG. 3, the chuck 32 and the base 34 are fastened by at least one fastener 36. Clearly, there is no contact between the chuck 32 and the base 34, with the chuck 32 being indirectly connected to the base 34 through the fastener 36. Therefore, the only channel for heat conduction is the fastener 36, whereby heat conduction between the chuck 32 and the base 34 can be effectively reduced. Herein, the base 34 is connected to a portion of an implanter and capable of supporting the chuck 32. Moreover, as an example, the chuck 32 may comprise a bottom layer, an intermediate layer, and a top layer. The bottom layer provides a mechanical and electrical interface to the base 34. The intermediate layer has an internal coolant jacket for distributing the coolant and an internal manifold for distributing wafer backside cooling gas. The top layer is a layer through which both an electrical connection and a cooling gas are fed.

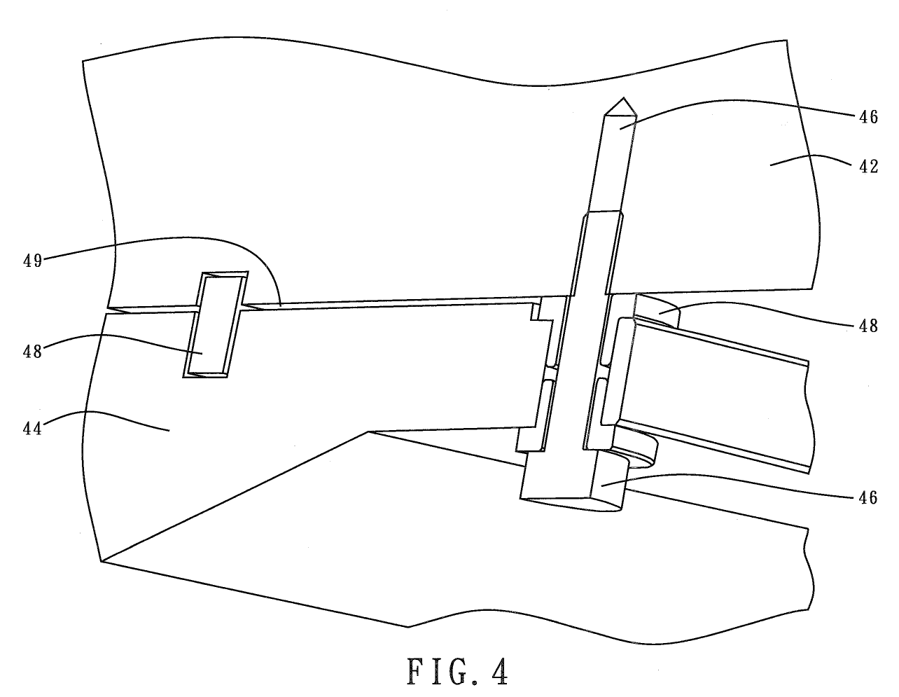

Significantly, when the thermal conduction through the fastener 36 can be remarkably reduced, the efficiency of the approach can be remarkably enhanced. Accordingly, as with the example shown in FIG. 4, the fastener 46 may be made of metal or other material encapsulated with thermal insulator 48. Besides, the thermal insulator 48 also can be located in a spaced relationship (i.e., not close to) the fastener 46, such that the chuck also is partially supported by the thermal insulator 48. Because fastener(s) 46 and thermal insulator 48 have small surface areas, such arrangement can remarkably reduce the contact area connecting the chuck 42 to the base 44. Notice that a gap 49 is introduced in this embodiment, such that the only thermal conduction path is by way of the fasteners 46. As a consequence of the efficiency of thermal conduction being significantly higher than that of thermal radiation, the gap 49 effectively reduces the heat transferred between the chuck 42 and the base 44. In one exemplary embodiment, the fasteners 46 are equally spaced around the edge of the base 44. In another exemplary embodiment, 12 small thermal insulators 46, made of Torlon® material or PEEK material, are equally spaced around the edge of the base 44. However, the essential concept of the invention does not limit the distribution of the fasteners 46 and thermal insulator(s) 48.

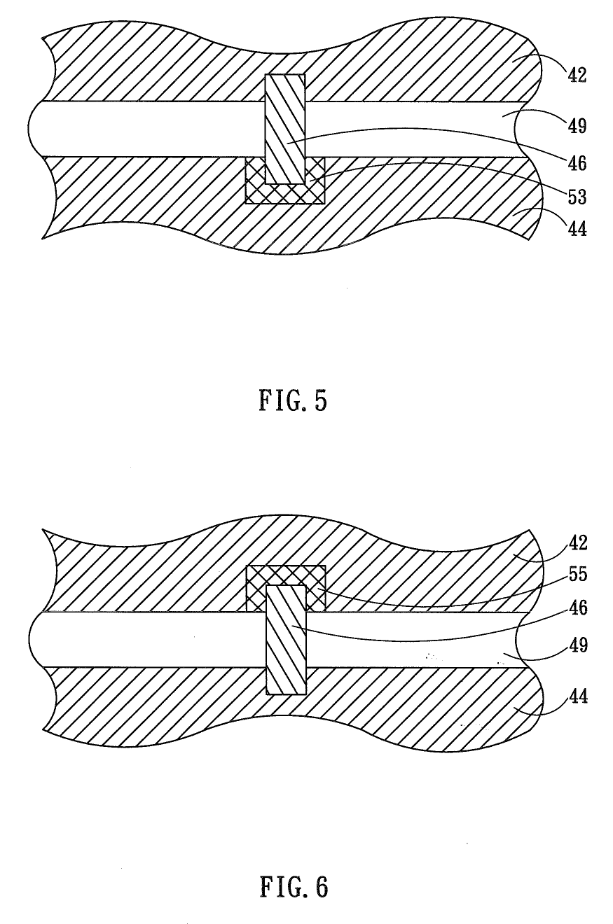

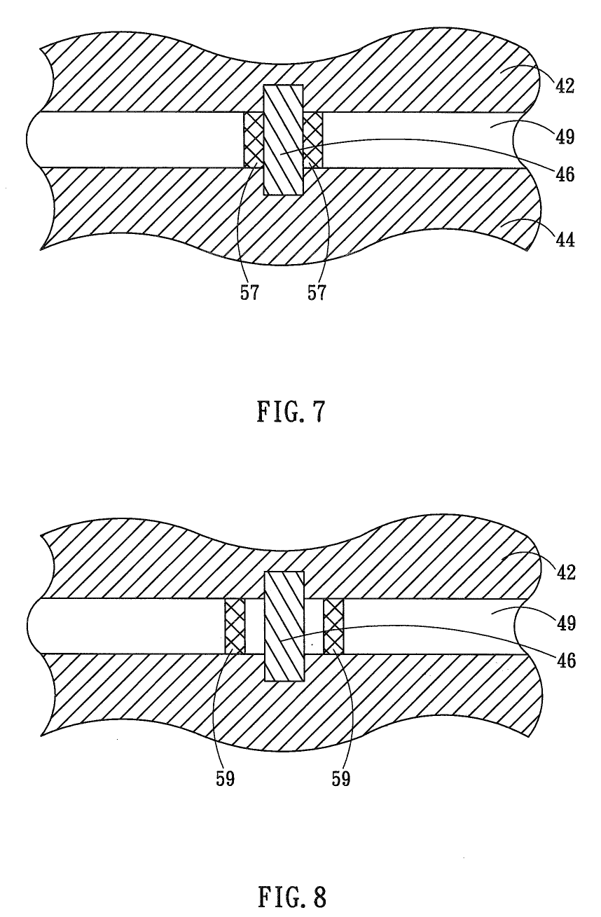

Provision of thermal insulation between the chuck 42 and the base 44 can be achieved in several ways. Referring to FIG. 5, in one embodiment, the fastener 46 may be thermally insulated from the base 44 by a first thermal insulator 53. With reference to FIG. 6, according to another embodiment, the fastener 46 may be thermally insulated from the chuck 42 by a second thermal insulator 55. Referring to FIG. 7, in still another embodiment, not only is the fastener 46 not thermally insulated from both the chuck 42 and the base 44, but also the chuck 42 is directly and/or partially thermally insulated from the base 44 by a third thermal insulator 57. FIG. 8 elucidates a further embodiment in which the fastener 46 is not thermally insulated from the chuck 42 and the base 44, but the chuck 42 is directly and/or partially thermally insulated from the base 44 by a fourth thermal insulator 59.

Besides the fasteners, the only other mechanical contacts between the platen (e.g., chuck) and the base are the coolant passageways and the wafer cooling gas passageway. Hence, in one embodiment, there is at least one o-ring for sealing the coolant passageway and/or the cooling gas passageway. Therefore, the only physical contact made with the chuck is through a collectively small area of fasteners, insulators and o-rings, corresponding to a conduction heat transfer that is quite small. Moreover, the effect of heat radiation is also quite small, and the heat transfer by radiation from the chuck to the base and other surroundings can be ignored.

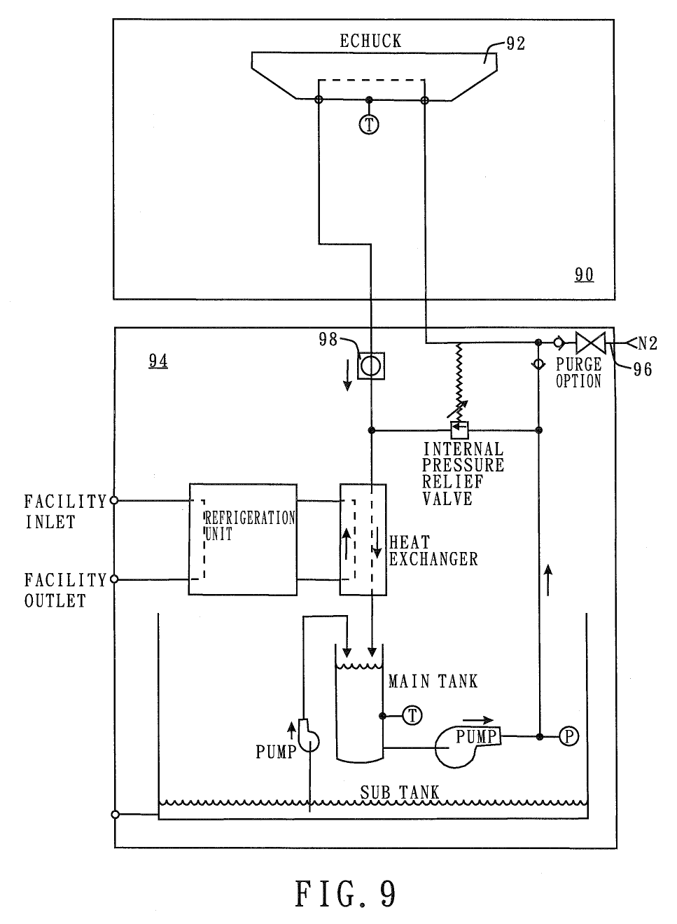

In addition to the above, the invention further includes another approach. With reference to FIG. 9, some embodiments of the invention relate to the improvement of the conventional water chiller 2 which uses DI water. FIG. 9 shows a block diagram of an ion implanter 90 that comprises a chuck 92 cooled by a cooling assembly 94. In this implementation, the cooling assembly 94 exchanges a coolant with a chiller outside of the ion implanter, such that the temperature of the coolant is increased when the coolant flows through the chuck and absorbs heat, and is decreased when the coolant flows through the chiller and exchanges heat with a refrigeration unit of the chiller. Without doubt, operation under 0° C. should be performed with a special coolant other than water to avoid freezing at atmospheric pressure and a chiller capable of chilling and pumping the selected coolant at sub-zero temperatures. Of course, all o-rings, pipelines, sensors and other elements should be compatible with the coolant. As embodied herein, the coolant should satisfy properties comprising one or more of low viscosity, high density, high thermal conductivity, and high specific heat at the sub-zero degree C. temperatures. The secondary consideration of coolant selection should target coolants having the properties of safety, acceptance and use inside of current semiconductor fabrication facilities. For example, the Fluorinert® FC-3283 fluid, available from 3M Company, can be selected as the coolant for cooling wafers at temperatures below 0° C. In addition, the SMC HRZ001-L-Z Thermo chiller available from SMC Pneumatics, Inc. of Indianapolis, can be used as the required chiller because of its temperature range, cooling capacity and pre-qualification.

According to an aspect of the present invention, design changes to this new cooling assembly can be provided for operation with this fluid at sub-zero degree C. temperatures. For example, part or all flexible tubing can be changed to be chemically compatible, reliable for sealing using standard fittings and/or extremely flexible at a predetermined temperature or temperature range. For example, all fittings can be changed to compression-type fittings with ferrules or externally clamped barbs. Moreover, as another example, all tubing and fittings can be covered with thermal insulation to prevent condensation on their outside surfaces. As a further example, all cold areas not covered by insulation can be enclosed and purged with dry purge gas, such as dry nitrogen or other very low dew point air, to prevent condensation. In one exemplary embodiment, all o-ring seals subject to contact with the fluid are changed to Ethylene Propylene Diene Monomer (EPDM), and/or all flow sensors are Proteus® flow sensors compatible with the coolant (Fluorinert FC-3283) and temperatures and calibrated specifically for the coolant at the expected operating temperature (sub-zero degree C.). Other features and components of the disclosed cooling assembly 34 can be the same as the SMC HRZ001-L-Z Thermo chiller, so that the detail description is omitted.

Although specific embodiments have been illustrated and described, it can be appreciated by those skilled in the art that various modifications may be made without departing from the scope and spirit of the present invention, which is intended to be limited solely by the appended claims.

What is claimed is:

1. A chuck assembly, comprising:
a chuck capable of holding a wafer;
a base capable of connecting to a portion of an implanter; and
at least one fastener that mounts said chuck on said base, such that said chuck and said base have no direct surface-to-surface contact.

2. The chuck assembly as set forth in claim 1, wherein said at least one fastener comprises a plurality of fasteners equally spaced on said base.

3. The chuck assembly as set forth in claim 1, wherein said at least one fastener comprises a plurality of fasteners, and the area between said fasteners and said chuck is significantly smaller than the area between said base and said chuck.

4. The chuck assembly as set forth in claim 1, wherein said fastener is thermally insulated from said base by a first thermal insulator.

5. The chuck assembly as set forth in claim 1, wherein said fastener is thermally insulated from said chuck by a second thermal insulator.

6. The chuck assembly as set forth in claim 1, wherein said chuck is thermally insulated from said base by another thermal insulator.

7. The chuck assembly as set forth in claim 6, wherein the area between said chuck and said other thermal insulator is significantly smaller than the area between said chuck and said base.

8. The chuck assembly as set forth in claim 1, further comprising one or more of the following:
an o-ring capable of sealing at least one coolant passageway that provides a coolant to said chuck for cooling said chuck; and
an o-ring capable of sealing at least one wafer cooling gas passageway that provides a gas to a backside of said wafer for cooling said wafer.

9. The chuck assembly as set forth in claim 1, wherein said chuck has a bottom layer, an intermediate layer, and a top layer, said bottom layer providing a mechanical and electrical interface to said base, said intermediate layer having an internal coolant jacket for distributing coolant and an internal manifold for distributing wafer backside cooling gas, and said top layer being a layer through which is fed an electrical connection and a cooling gas.

10. An ion implanter, comprising:
an ion beam generation assembly for generating an ion beam; and
a chuck assembly, comprising:
a chuck capable of holding a wafer to be implanted by said ion beam;
a base capable of connecting to a portion of said ion implanter; and
at least one fastener that mounts said chuck on said base, such that said chuck and said base have no direct surface-to-surface contact.

11. The ion implanter as set forth in claim 10, further comprising a cooling assembly for cooling said wafer, wherein said cooling assembly exchanges a coolant with a chiller outside of said ion implanter, such that the temperature of said coolant is increased when said coolant flows through said chuck and absorbs heat, and such that the temperature of said coolant is decreased when said coolant flows through said chiller and exchanges heat with a refrigeration unit inside said chiller, wherein said coolant is a liquid having low viscosity, high density, high thermal conductivity, and high specific heat within a predetermined operating temperature range.

12. The ion implanter as set forth in claim 1 1, said cooling assembly using a plurality of flexible tubes that are chemically compatible, reliable for sealing and extremely flexible during a predetermined operation temperature range, said cooling assembly using a plurality of fittings that are compression-type with ferrules, and said cooling assembly also using a plurality of tubes and said fittings that both are covered with thermal insulation.

13. The ion implanter as set forth in claim 11, said cooling assembly using a dry purge gas enclosed in a specific portion of said cooling assembly that is not covered by said thermal insulation, said cooling assembly using a plurality of o-rings that are compatible with said coolant, and said cooling assembly also using a flow sensor that is compatible with said coolant and calibrated specifically for said coolant at an expected operating temperature.

14. The ion implanter as set forth in claim 10, wherein a plurality of said fasteners are equally spaced around said base.

15. The ion implanter as set forth in claim 10, wherein the area between said chuck and said fasteners is significantly smaller than the area between said chuck and said base.

16. The ion implanter as set forth in claim 10, further comprising a first thermal insulator located between said chuck and said base for providing thermal insulation.

17. The ion implanter as set forth in claim 10, further comprising a second thermal insulator located between said chuck and said fastener for providing thermal insulation.

18. The ion implanter as set forth in claim 10, further comprising another thermal insulator located between said base and said fastener for providing thermal insulation.

19. The ion implanter as set forth in claim 18, wherein the area between said chuck and said other thermal insulator is significantly smaller than the area between said chuck and said base.

20. The ion implanter as set forth in claim 10, wherein said chuck has a bottom layer, an intermediate layer, and a top layer, said bottom layer providing a mechanical and electrical interface to said base, said intermediate layer having an internal coolant jacket for distributing coolant and an internal manifold for distributing wafer backside cooling gas, and said top layer being a layer through which an electrical connection and a cooling gas are fed.
